(19) United States
(12) Patent Application Publication
(10) Pub. No.: US 2009/0272426 A1
(43) Pub. Date: Nov. 5, 2009

(54) SOLAR CONCENTRATOR

(76) Inventor: Christopher J. Winscom, Histon (GB)

Correspondence Address: Raymond L.Owens;Patent Legal Staff, Eastman Kodak Company, 343 State Street, Rochester, NY, 14650-2201, US

(21) Appl. No.: 12/414,722

(22) Filed: Mar. 31, 2009

(30) Foreign Application Priority Data
May 3, 2008 (GB) 0808153.1

(51) Int. Cl. H01L 31/055

(52) U.S. Cl. 136/247

(57) ABSTRACT

A radiation concentrator suitable for use in concentrating solar radiation for efficient and low cost solar photovoltaic use, especially for example in window-mounted devices, has a radiation-transmissive element for receiving incident radiation and includes a radiation-absorbing material for absorbing incident radiation and emitting emissive radiation, a radiation output for transmitting concentrated emissive radiation, the transmissive element acting as a wave-guide for guiding the emissive radiation to the radiation output. The concentrator is characterized by the radiation-absorbing material comprising one or more photoluminescent dyes capable of phosphorescence which exhibit a high quantum yield of phosphorescent emission that is spectrally shifted from the material's absorption.

### FIELD OF THE INVENTION

The present invention relates to the field of radiation concentration, especially solar concentration, by which radiation striking a surface can be effectively concentrated to a more intense, concentrated or higher energy form. More particularly, the invention relates to a radiation concentrator, especially a solar radiation concentrator, a material for use in a radiation concentrator, a method of concentrating incident radiation and to a method of making a radiation concentrator.

### BACKGROUND OF THE INVENTION

Radiation concentration is finding increasing relevance for the purpose of improving the efficiency of photovoltaic (PV) cells used for power generation by improving the intensity or concentration of incident solar radiation on the cells. Photovoltaic cells are a means for converting incident radiation, typically actinic radiation such as solar radiation, into electrical energy and is considered a major component of renewable energy systems.

Many PV cells, however, require for their manufacture materials that are expensive and energy-intensive in producing. Accordingly, in order to improve the operating efficiency of solar PV cells, methods of improving the efficiency of conversion of solar radiation to electrical energy per unit area are being sought. The most productive means of doing so is to increase the intensity of solar radiation on the PV cells, by concentration.

Two broad classes of solar concentrator are being developed. A first is a geometric solar concentrator, which can take the form of a reflective or refractive concentrating element. A reflective or refractive (geometric) solar concentrator operates by efficiently redirecting or focusing solar radiation incident on concave reflective surfaces or lenses to a solar PV cell or cell array. A refractive solar concentrator operates by optically focusing incident radiation on a large surface onto the smaller PV cell or cell array surface. These have the disadvantage that they are required to track the direction of incident radiation for efficient concentration and also are not very effective in diffuse light (e.g. cloudy weather). The second class might be termed absorptive-emissive concentrators and act by absorbing the incident radiation and re-emitting radiation to a PV cell or cell array.

The absorptive-emissive form of concentrator typically comprises a sheet of radiation-receptive material, the sheet itself being typically transparent, doped with a material capable of absorbing the incident radiation and then re-emitting radiation which is directed via a waveguide to a PV array, typically at the edge of the sheet (and thereby covering a much smaller area than if employed as the direct radiation absorber). The waveguide, which directs the re-emitted radiation to the edge of the sheet is typically the sheet itself, by trapping the re-emitted radiation within the sheet by internal reflection. The absorptive-emissive radiation concentrators have the advantage that they do not need to track incident radiation for effective trapping of incident radiation and they are also effective in diffuse light.

The design of such absorptive-emissive radiation concentrators are often intended to enable large area collection of radiation from transparent surfaces, such as the windows of buildings. The PV elements may be embedded in one or more edges of the window. The pane of the window ideally has embedded therein absorbing materials capable of absorbing actinic radiation across a range of wavelengths, which re-emit at wavelengths matching the response of the PV element used.

The absorbing materials are typically fluorescent dyes or pigments which absorb energy within the visible spectrum and efficiently re-emit in a relatively narrow bandwidth. A significant proportion of the re-emitted radiation is trapped within the waveguide formed by the pane by total internal reflection and impinges upon the PV element configured at the edge of the pane, which can then convert the radiation into electrical energy.

There are, however, several problems with this form of absorptive-emissive radiation concentrator, associated with the difficulty in finding suitable fluorescent dyes as absorbing materials. Several requirements have been identified for effective and efficient radiation concentration using absorptive-emissive systems. The absorbing material must be capable of: efficiently absorbing across the range of wavelengths of the incident radiation; emitting radiation at a wavelength suitable for absorption by the energy converter (e.g. photovoltaic element); emitting radiation with a high quantum yield (by which it is meant the energy of emitted radiation at that wavelength is a high proportion of the energy of absorbed radiation); and not re-absorbing emitted radiation. Further required characteristics for solar concentrators, for use in window arrangements, include the requirement of stability of the radiation absorber under illumination and the requirement that the materials are transparent and remain transparent at luminescent wavelengths.

Typical organic fluorescent dyes having broad band absorption and emission have absorption-emission spectra which have significant levels of overlap, which results in re-absorption of emitted radiation. This has the effect of reducing the area of effective solar collection to areas a few centimeters from the edge of the radiation receiver (e.g. window pane) near the PV element.

There have been several attempts to overcome the difficulties associated with such fluorescent absorptive-emissive systems.

For example, in U.S. Pat. No. 4,110,223, there is described a multiple layer collection device, each layer acting as an independent solar concentrator and doped with a separate fluorescent dye having a relatively narrow bandwidth of absorption and a narrow emission bandwidth. By this method the effective absorptive bandwidth of the multiple layers covers a broad range of wavelengths. However, the disadvantages with this method are that the edge-mounted PV element is required to be three times the size (to cover three edges) and it is difficult to identify appropriate fluorescent dyes that absorb at different wavelengths but emit at the same narrow wavelength suitable for the PV element whilst meeting the other requirements of transparency, photo-stability, high Stokes' shift, etc.

U.S. Pat. No. 4,188,239 describes a solar concentrator comprising a planar waveguide at least one edge of which impinges upon a photovoltaic cell, the waveguide comprising an active luminescent species responsive to a portion of the incident solar radiation to generate luminescent radiation trapped within the waveguide and delivered to the photovoltaic cell by total internal reflection. The device further comprises a backing layer comprising a mirror having deposited thereon a rough, diffusing layer of particulate solid inorganic phosphorescent material, activated by the shorter wavelength solar radiation not absorbed by the luminescent species in the waveguide. The phosphorescent material produces on activation a longer wavelength emission that is reflected back into the waveguide and is of a wavelength that may activate the luminescent material therein. The specific example described uses the reflective phosphorescent particulate layer to reintroduce transmitted incident radiation into the waveguide at a longer wavelength, whilst the waveguide contains two fluorescent materials for generating the fluorescence to be captured by the photovoltaic cell. Whilst this solution assists in re-capturing incident radiation outside the spectrum of activation of the luminescent material contained within the waveguide, the luminescent material itself, which in the specific example is sulforhodamine 101 organic fluorescent dye, remains unsatisfactory for use in the waveguide in that there is insufficient separation between the absorption and emission spectra, which leads to an unsatisfactory overlap and significant re-absorption. A further problem with fluorescent dye-based systems has been the tendency for the dye to degrade over time due to exposure to solar ultraviolet light, although some efforts to identify more stable fluorescent dyes have been made.

U.S. Pat. No. 6,476,312 (Barnham et al) attempts to overcome the shortcomings of absorptive-emissive radiation concentrators that use organic fluorescent dyes as the absorbing materials and describes a radiation concentrator for use with a photovoltaic device, which comprises a wave-guide containing a plurality of quantum dots. The quantum dots cause a red-shift of incident radiation which is internally reflected by the waveguide to a waveguide output. Quantum dots are said to be of particular benefit due to their luminescent efficiency and the tenability of absorption thresholds and size of red shifts. The use of quantum well cells can tune the band-gap. According to U.S. Pat. No. 6,476,312, by incorporating quantum dots of a certain spread of sizes, the red-shifted radiation can be controlled to minimize overlap with the absorption spectrum and match the required bandwidth of the photovoltaic element. Whilst quantum dots possess the characteristic of suitable broad-band visible absorption and narrow band emission, they suffer from the common characteristic of small Stokes' shift, which reduces the path length of emitted radiation due to re-absorption. Whilst efforts to increase that path length via controlling the spread of size of quantum dots have been described, the practical efficiency has yet to be demonstrated (e.g. Gallagher et al, Solar Energy 81 (2007) 813-821), the assumption being that whilst a spread of dot sizes increases the red shift of the absorption and emission peaks, the absorption spectrum becomes broader providing some overlap with the emission spectrum.

It would be desirable to provide improved absorption-emission concentrator systems that can allow radiation concentrators to be provided which enable improved PV absorption efficiency whilst overcoming the problems with prior art systems.

### PROBLEM TO BE SOLVED BY THE INVENTION

It is an object of the invention to provide a radiation concentrator system, especially a solar concentrator, for efficiently concentrating incident radiation upon a surface to a radiation capture device.

It is a further object of the invention to provide a photoluminescent material for use as an absorbing material in radiation concentrators, especially solar concentrators, for photovoltaic elements, the photoluminescent material being stable under illumination, having an absorption spectrum in the visible region, a narrow band emission spectrum, a high quantum efficiency of emission and a low rate of re-absorption of emitted radiation

It has been found by the present inventor that the required characteristics of an absorbing material for an absorptive-emissive solar concentration are provided by certain phosphorescent dyes.

### SUMMARY OF THE INVENTION

Accordingly, in a first aspect of the invention, there is provided a radiation concentrator comprising a radiation-transmissive element having a transmissive surface for receiving incident radiation, a radiation-absorbing material for absorbing incident radiation and emitting emissive radiation, a radiation output for transmitting concentrated emissive radiation and a wave-guide for guiding the emissive radiation to the radiation output, characterized in that the radiation-absorbing material comprises one or more photoluminescent dyes capable of phosphorescence, the dye or dyes exhibiting a high quantum yield of phosphorescent emission that is spectrally shifted from the material's absorption.

According to a second aspect of the invention, there is provided an apparatus for converting incident radiation to electrical energy, said apparatus comprising a radiation concentrator as defined above and a photovoltaic device coupled to said radiation concentrator.

According to a third aspect of the invention, there is provided a method of capturing incident radiation comprising the steps of: providing a concentrating element with a surface transmissive to incident radiation, disposing on and/or within said element a radiation-absorbing material comprising a phosphorescent dye, the radiation-absorbing material being capable of absorbing at least a portion of said incident radiation and capable of emitting emissive radiation spectrally shifted from its absorption spectrum; and providing in association with the element a radiation output for feeding concentrated radiation from the element, wherein the external surfaces of the element form a waveguide to direct emissive radiation to the radiation output.

According to a fourth aspect, there is provided a method of converting incident radiation into electrical energy comprising the steps defined above for capturing incident radiation and the further step of providing a photovoltaic element to be optically coupled with the radiation output, whereby concentrated emissive radiation impinges upon said photovoltaic element, the emission spectrum of the phosphorescent dye and the response of the photovoltaic element being selected such that the photovoltaic element is responsive to radiation within the phosphorescent dye's emission spectrum.

According to a fifth aspect of the invention, there is provided a method of configuring a radiation concentrator said radiation concentrator comprising a radiation-transmissive element having a transmissive surface for receiving incident radiation, a radiation-absorbing material for absorbing incident radiation and emitting emissive radiation, a radiation output for transmitting concentrated emissive radiation and a wave-guide for guiding the emissive radiation to the radiation output, the radiation-absorbing material comprising one or more photoluminescent dyes capable of phosphorescence, the dye or dyes exhibiting a high quantum yield of phosphorescent emission that is spectrally shifted from the material's absorption, the method comprising the steps of: selecting a radiation-transmissive element of a given size whereby the mean distance from the centre of the transmissive surface to the edge thereof is given by L; selecting a dye having an extinction coefficient as a function of wavelength of ε(λ); doping the transmissive element of the concentrator with the dye at a selected concentration c, said size of element and identity and concentration of dye being selected such that the approximated loss factor is 0.5 or less, when given by the following formula

loss factor˜1−[∫10^{-ε(λ)c.L}.I(λ).(λ⁻²).dλ/∫I(λ).(λ⁻²).dλ]

wherein the integrations are over the wavelength range of the emission,

I(λ) is the relative intensity of the emission as a function of wavelength,

ε(λ) is the molar extinction coefficient (M⁻¹ cm⁻¹) of the dye's absorption as a function of wavelength,

c is the molar concentration of the dye in the absorbing medium, and

L is a mean distance (cm) approximated as the distance from the centre of the medium area to its edge.

According to a sixth aspect of the invention, there is provided a radiation concentrator comprising a radiation-transmissive element having a transmissive surface for receiving incident radiation, the surface having a size given by the mean distance from the centre of the transmissive surface to its edge of L, a radiation-absorbing material for absorbing incident radiation and emitting emissive radiation, a radiation output for transmitting concentrated emissive radiation and a wave-guide for guiding the emissive radiation to the radiation output, the radiation-absorbing material comprising one or more photoluminescent dyes capable of phosphorescence, the dye or dyes exhibiting a high quantum yield of phosphorescent emission that is spectrally shifted from the material's absorption and having an extinction coefficient as a function of wavelength of ε(λ) and incorporated into the concentrating element at concentration c, the radiation concentrator being configured such that

loss factor˜1−[∫10^{-ε(λ)c.L}.I(λ).(λ⁻²).dλ/∫I(λ).(λ⁻²).dλ]≦0.5

wherein the integrations are over the wavelength range of the emission,

I(λ) is the relative intensity of the emission as a function of wavelength,

ε(λ) is the molar extinction coefficient (M⁻¹ cm⁻¹) of the dye's absorption as a function of wavelength,

c is the molar concentration of the dye in the absorbing medium and L is a mean distance (cm) approximated as the distance from the centre of the medium area to its edge.

According to a seventh aspect of the invention, there is provided an absorbing material for use in a radiation concentrator, the absorbing material comprising a mixture of at least two components, an incident-absorbing component and a product-emissive component, said incident-absorbing component being capable of absorbing radiation in the visible spectrum and emitting radiation at a wavelength matched to the absorption spectrum of the product-emissive component, the product-emissive component comprising at least one phosphorescent dye having a high quantum yield of phosphorescence at a desired wavelength that is spectrally shifted from the absorbance of the absorbing material.

### ADVANTAGEOUS EFFECT OF THE INVENTION

The radiation concentrator according to the invention is capable of efficiently and effectively concentrating incident radiation upon a large surface area of the concentrator to radiation output (e.g. to a photovoltaic device) of relatively low surface area (e.g. an edge of a sheet). The concentrator by having embedded therein a phosphorescent dye (or dye system comprising a phosphorescent dye) capable of absorbing radiation corresponding to incident light and emitting at a wavelength that is spectrally shifted, preferably spectrally separated, from its absorption spectrum is capable of concentrating incident light over a wide area with a minimum amount of self-absorption of the emitted light by the dye. Accordingly, the ratio of radiation-incident area to photovoltaic cell area is increased significantly over corresponding fluorescent dye systems as is concentration efficiency.

### BRIEF DESCRIPTION OF THE DRAWINGS

FIG. 1 is a diagrammatic representation of an experimental arrangement to determine attenuation of luminescence for different dyes;

FIG. 2 is a graph of intensity against wavelength for the absorption and emission spectra of a fluorescent dye;

FIG. 3 is a graph of transmission (%) against path length for a fluorescent dye in the apparatus of FIG. 1;

FIG. 4 is a graph of intensity against wavelength for the absorption and emission spectra of a phosphorescent dye;

FIG. 5 is a graph of transmission (%) against path length for a phosphorescent dye in the apparatus of FIG. 1.

### DETAILED DESCRIPTION OF THE INVENTION

A radiation concentrator according to the present invention, which is suitable for use as a solar concentrator and may be coupled to a photovoltaic device, comprises a transmissive surface which is capable of receiving radiation (e.g. solar radiation) into a concentrating element and embedded in the concentrating element a radiation-absorbing material capable of absorbing the incident radiation and emitting emissive radiation in high quantum yield and sufficiently spectrally shifted from its absorption spectrum. A substantial proportion of the emissive radiation is internally reflected on the surfaces of the concentrating element which acts as a waveguide delivering the emissive radiation to one or more radiation outputs, which may be optically and/or physically coupled, for example, to a photovoltaic element capable of converting the photo-energy into electrical energy. In accordance with the present invention, the radiation-absorbing material is characterized by comprising a phosphorescent dye having an emission spectrum spectrally separated from its absorption spectrum.

Photoluminescent dyes which rely on fluorescence re-emission, such as those used in prior art dye-based concentrator systems, exhibit a spectral shift from the maximum of the absorption to the maximum of the emission, referred to as the Stokes' shift. This shift is typically on the order of one to two intervals of the dominant vibrational progression giving rise to the absorption and emission envelopes. A typical vibrational interval in the range 1000-2000 cm⁻¹ translates to a range of 20-80 nm in the visible region of the spectrum (400-700 nm). As a result of the usually poorly-resolved vibrational progressions, the typical absorption and emission profiles have broad asymmetric envelopes with respect to their respective maxima. On a common wavelength scale, typical absorption and emission profiles appear almost as mirror images of each other. The sum of half-widths characterizing the facing edges of the absorption and emission profiles are generally on the same order of one to two vibrational intervals, with the result that there can be very significant overlap. This leads to re-absorption of the emission. As a result the effective capture area on a radiation or solar concentrator, which concentrates radiation to an output at the edge of a sheet, is typically only on the order of a few centimeters depth around the periphery.

Phosphorescence is herein defined as any luminescence arising from an optical transition between two states of different electron spin multiplicity, for example in neutrally-charged organic molecules, like benzophenone, between the lowest-lying triplet state (T₁) to the ground state singlet (S₀), or of Cr³⁺ in ruby from the lowest-lying doublet states (²E, ²T₁) to its ground state quartet (⁴A₂), or in Eu³⁺ complexes, the emission from the excited (⁵D₀) state to its (⁷F₂) ground state. Phosphorescent dyes for use in the present invention may exhibit any such phosphorescent luminescence, but those arising from triplet-singlet transitions (e.g. T₁-S₀) are preferred.

In the radiation concentrator of the present invention, the radiation-absorbing material comprises high quantum yield phosphorescent dye with a phosphorescence sufficiently spectrally shifted from the absorption characteristics of the material. With such efficient phosphorescent dyes, fluorescent emission is disadvantaged by an efficient intersystem crossing and the phosphorescent emission dominates. In neutral organic molecules, for example, where phosphorescence originates from the lowest lying triplet excited state, the net absorption—emission spectral shift is enhanced by an extra contribution arising from the S₁-T₁ energy gap, which typically lies in the range of 2000-8000 cm⁻¹ (translating to about 40-200 nm within the visible region). Overlap between absorption and emission is thus markedly reduced and re-absorption of the phosphorescent emission becomes negligible. Thereby, the effective collection area on a sheet solar collector delivering concentrated radiation to the edges is significantly increased (and thus the effective concentration effect is improved).

By sufficiently spectrally shifted from its absorption spectrum, it is meant the peak of the shifted emission spectrum is shifted from the peak of the absorption spectrum such that the overlap of absorption spectrum of the dye and its phosphorescent emission spectrum is minimized. Preferably, the absorption and emission maxima are separated by at least twice the sum of the half-width half-maximum (HWHM) values of the facing halves of the absorption and emission envelopes. More preferably the separation should be at least three times the sum of the HWHM's.

In the embodiment of the invention in which a photovoltaic element is coupled with the radiation concentrator and the response of the coupled photovoltaic element is closely matched to the emission spectrum of the dye, practical minimization of re-absorption may be calculated to take into account the extinction coefficient of the dye as a function of wavelength, the concentration of the dye in the absorbing medium, the relative intensity of the dye's emission as a function of wavelength and the distance from all points of absorption within the area of the absorbing medium to the edge-lining solar cells. An approximation of the fractional loss due to re-absorption is given by:

loss factor˜1−[∫10^{-ε(λ)c.L}.I(λ).(λ⁻²).dλ/∫I(λ).(λ⁻²).dλ]

wherein the integrations are over the wavelength range of the emission,

I(λ) is the relative intensity of the emission as a function of wavelength,

ε(λ) is the molar extinction coefficient (M⁻¹ cm⁻¹) of the dye's absorption as a function of wavelength

c is the molar concentration of the dye in the medium of the concentrating element and

L is a mean distance (cm) approximated as the distance from the centre of the medium area to its edge.

The loss factor is thus dependent on the overall area of the medium.

Based on this approximation to loss factor in the system, the degree of overlap of the absorption and emission spectra of any particular phosphorescent dye (or dye system) for use in accordance with the present invention is preferably such that the loss factor is 0.5 or less, more preferably, 0.3 or less, still more preferably, 0.1 or less and most preferably 0.05 or less.

If the emission profile is not perfectly matched to the response of photovoltaic element, then any overlap of the absorption and emission spectrum contributing to the re-absorption loss factor occurring within the response bandwidth of a coupled photovoltaic element is preferably minimized by the means referred to above, and still more preferably, there is no overlap of absorption and emission spectrum contributing to the loss factor at wavelengths matched to the response of a coupled photovoltaic device.

When coupled to a photovoltaic element, the concentrator and PV element are configured such that the response of the PV element matches at least a portion of the phosphorescent emission spectrum. Preferably, the PV element is responsive across at least 50% of the emission spectrum at half width half maximum, more preferably at least 75% and still more preferably at least 90% and most preferably totally matched. To the extent to which the PV element response is configured to match the phosphorescent emission of the dye system, the loss factor in the system is preferably, 0.5, 0.3, 0.1, 0.05, and most preferably substantially no loss due to re-absorption occurs at the wavelength of the phosphorescent emission to which the PV element is responsive.

Any suitable such photophosphorescent material may be used as the photoluminescent dye. By photophosphorescent material as used herein it is meant a photoluminescent material that exhibits phosphorescence. The photo-phosphorescent material is preferably chosen to match the required radiation output, for example a wavelength of response of the chosen photovoltaic element used to capture and convert the concentrated radiation. Ideally, the photo-phosphorescent material used in the concentrator of the present invention is stable to illumination (especially actinic radiation), has a high quantum yield, has an emission spectrum that can be energy matched to a coupled photovoltaic element and an absorption spectrum that is substantially spectrally separated from its emission spectrum (e.g. by at least twice the sum of HWHMs of the respective spectra). Preferably, the photophosphorescent material has an absorption spectrum that is capable of absorbing solar radiation and preferably a substantial portion of the spectrum of solar radiation.

Preferably, the photophosphorescent material is a phosphorescent organometallic dye.

The quantum yield of the photophosphorescent material is preferably 0.1 or more, more preferably greater than 0.3, still more preferably greater than 0.5 and most preferably greater than 0.8. Where available and subject to the suitability for use in such a system, the most preferred photophosphorescent materials are those with a quantum yield of 1 or within 10% thereof. Suitable such photophosphorescent materials are typically characterized by strong singlet-singlet absorption (or a similarly spin-allowed absorption), efficient intersystem crossing to the triplet state manifold (or similar manifold having a different electron spin multiplicity to the states involved in the absorption) and exhibiting a high quantum yield of phosphorescent emission. Any absorption between the states involved in the phosphorescent emission in suitable phosphorescent materials, i.e. singlet ground state to triplet excited state for most organic molecules, is typically very weak whereby self-absorption of emitted energy is minimized.

Preferred classes of photophosphorescent materials for use in accordance with the present invention include main group, transition metal and lanthanide coordinating complexes, having the general formula (M)ₚ (L)_{q}, wherein (M) may be a heavy metal atom or ion, p may be equal to or greater than 1, and (L) is a ligand system, wherein q may be equal to or greater than 1, comprising one or more single- (L) or multidentate (L̂L̂ . . . ) organic ligands bound to metal. For p>1, the metals may be the same or different and the ligands may bind to the same or different metal atoms or ions.

For a tolerable phosphorescent quantum yield performance up to 0.1. the metals comprising (M) may be chosen from:

main group atoms (atomic numbers 20, 31-34, 38, 49-52, and 56, 81-84) and particularly germanium(II), tin(II), and lead(II), such as those described by H. Nikol et al, Inorg. Chem. 31,1992, 3277 and J. Am. Chem. Soc. 113, 1991, 8988, as well as antimony and bismuth complexes, complexed with ligands such as azaindolyl phenyl ligands; or

group 12 atoms, particularly zinc(II), such as those described by Q.-D. W. R. Lui et al, Dalton Trans. 2004, 2073, cadmium(II) such as those described by V. W.-W. Yam et al, New J. Chem. 23, 1999, 1163, and mercury(II) such as those described by M. A. Omary et al, Inorg. Chem. 42, 2003, 2176; or

transition metals from the first row (atomic numbers 22 to 29), particularly chromium(III) such as those described in: A. D. Kirk, Coord. Chem. Rev., 39, 1981, 225; A. A. Jamieson et al, Coord. Chem. Rev., 39, 1981, 121; and L. S. Forster, Chem. Rev., 90, 1991, 331, and Cu(I), such as those described in V. W-W. Yam et al, J. Organomet. Chem., 578, 1999, 3.

Still heavier coordinating metals promote more efficient intersystem crossing into the phosphorescent states of the complex, thereby improving the quantum yield of the phosphorescence, so for extended performance >0.1, (M) is chosen from: preferably second row transition metals (atomic number 40 to 47), especially ruthenium(II), in complexes preferably containing bidentate diimine ligands (e.g. bipyridine, phenanthroline) such as those described by A. Buskila et al, J. Photochem. Photobiol A 176, 2004, 381 and C. Goze et al, New J. Chem. 27, 2003, 1679, rhodium(III) preferably in cyclometallated diimine complexes such as those described by K. K-W. Lo et al, J. Chem. Soc. Dalton 2003, 4682, palladium(II) such as those described by F. Neve et al, Organometallics 21, 2002, 3511 and J. B. Callis et al J. Mol. Spectrosc. 39, 1971, 410, and silver(I), such as those described by Y. Y. Lin et al, Organometallics 21, 2002, 2275, and also prominently palladium (II) complexes; silver (I) complexes; or

more preferably rare earth atoms/ions of the lanthanide series, (atomic number 57 to 71) wherein complexes that may be used as photo-luminescent materials in the present invention are preferably with ligands exhibiting the ability of their excited triplet state to transfer energy to the emitting state of the lanthanide ion. Ligands with the ability to strongly bind to the lanthanide ions, such as cryptands, calixarenes, 1,3-diketones, carboxylic acid derivatives, heterobiaryl ligands and other macrocyclic ligands, offer the most rigid structures to minimize non-radiative deactivation in complexes with, especially, europium(III) such as those described in P. Coppo et al, Angew. Chem. Int. Ed. 44, 2005, 1806, terbium(III) such as those described in N. Sabbattini et al, Coord. Chem. Rev. 123, 1993, 201, samarium(III) such as those described in H. Hakala et al, Inorg. Chem. Commun. 5, 2002, 1059, and gadolinium(III), such as those described in A. Strasser et al, Chem. Phys. Letters 379, 2003, 287; or

most preferably from third row transition metals (atomic numbers from 72 to 79), especially rhenium(I), osmium(II), iridium(III) platinum(II) and gold(I), i.e. complexes of isolectronic metal ions with d⁶, d⁸ and d¹⁰ electron configurations.

Examples of useful third row transition metal complexes include:

rhenium(I) complexes such as tricarbonylrhenium(I) α,α′-diimine complexes (e.g. [Re(N̂N)(CO)₃(L)]ⁿ⁺, where N̂N is the diimine ligand, L is a monodentate ligand and n is 0 or 1, particularly those reported in L. Sacksteder et al, JACS, 115, 1993, 8230 and those where L is an acetylide moiety;

biscarbonylrhenium(I) α,α′-diimine complexes (e.g. bipyridine coordinated complexes such as cis-, trans-[Re(X₂bpy)(CO)₂(PR₃)(Y)]ⁿ⁺ where X is Me, H or CF₃, R is OEt or Ph, Y is halogen or pyridine), as in K. Koike et al, Inorg. Chem. 39, 2000, 2777; or tetracabonylrhenium(I) complexes Re(CO)₄L, as in R. Czerwieniec et al, Inorg. Chem. Comm. 8, 2005, 1101;

osmium (II) complexes, such as simple osmium (II) α,α′-diimine complexes which emit in the far red/near IR region and have high quantum yields, are of the form Os(II)(N̂N)₂(L̂L) or Os(II)(N̂N)₂L₂ or Os(II) (N̂N)(L̂L)AB where N̂N is e.g. phenanthroline or bipyridine or other α,α′-diimine, L̂L is a bidentate ligand coordinated through phosphorus or arsenic atoms, or L may be an isolated phosphorus or arsenic coordinating ligand and A, B may be, e.g. carbonyl and halogen, such as reported by B. Carlson et al J. Am. Chem. Soc. 124, 2002, 14162, and J. Lu et al, Synth. Met. 155, 2005, 56;

iridium (III) complexes, which span the phosphorescence quantum yield range of 0.1 to 0.9, and useful emission wavelength range of 470-640 nm, having the general formulae Ir(III)(ĈN)₃₋ₙ(L′̂L″)ₙ or Ir(III)(ĈN)₃₋ₙ L₂ₙ, wherein n=0, 1, or 2, (ĈN) is a 2-phenyl azaaromatic molecule, e.g. variously substituted 2-phenyl pyridine, 2-phenyl quinoxaline, 2-phenyl benzthiazole, etc., (L′̂L″)ₙ may be a ligand containing two coordinating centres such as N, O, etc. which may be the same as in acetylacetone or bipyridyl or different, as in F.-M. Hwang et al, Inorg. Chem. 44, 2005, 1344, S. J. Lee et al, Curr. Appl. Phys. 5, 2005, 43, A. Kapturkiewicz et al, Electrochem. Com. 6, 2004, 827, S. Lamansky et al, Inorg. Chem. 40, 2001, 1704, or in the case of supplementary monodentate ligands L may be, e.g. CN, SCN, NCO as in M. K. Nazeeruddin et al, J. Am. Chem. Soc. 125, 2003, 8790. Interlinking two iridium centres using extended phenylpyridyl moieties, as in P. Coppo et al, Chem. Com. 15 2004, 1774, are also known to exhibit substantial quantum yields; platinum (II) complexes, which also span the phosphorescence quantum yield range 0.1 to 0.9, mostly emit in the range 550-650 nm, and generally involve at least one cyclometalated multidentate ligand in coordination modes (e.g. N̂N, N̂N̂C, ĈN̂C, N̂ĈN, N̂N̂N, N̂N̂N̂N, N̂N̂ĈC, ŜS, ŜĈS). High quantum yield porphyrins as in D. L. Eastwood et al, J. Mol. Spectrosc. 35, 1970, 359 are amongst the earliest known examples; other quadridentate examples as in J. Kavitha et al, Adv. Funct. Mater. 15, 2005, 223 and Sandrini et al, J. Am. Chem. Soc. 109, 1987, 7720; tridentate- with other monodentate ligands, as in J. A. G. Williams et al, Inorg. Chem. 42, 2003, 8609 and Q.-Z. Yang et al, Inorg. Chem. Comm. 41, 2002, 5653, and bidentate- with other monodentate- and bidentate ligands, as in J. Brooks et al, Inorg. Chem. 41, 2002, 3055; and

gold (I) complexes, especially wherein the mononuclear complexes containing carbine, phosphine, thiolate and acetylide exhibit weak intra-ligand phosphorescent states in the 400-500 nm region, and a few examples of ligand to metal charge transfer states emitting in the 600-700 nm region, as in J. M. Forward et al, Inorg. Chem. 34, 1995, 6330, more generally weak intermolecular bonding leads to numerous di- tri- and polynuclear examples.

In another preferred embodiment, the photoluminescent material comprises a transition metal complex, which is optionally heterometallic. In general, at least one of the metals involved is taken from the prominent third row transition metals (rhenium(I), osmium(II), iridium(III), platinum(II) and gold(I)) identified above, and the other partner metals may belong to the first, second or third transition series, or the lanthanide series already described. These complexes may involve weak metal-metal interactions, e.g. binuclear gold(I) complexes as in V. W.-W. Yam et al, J. Organometallic Chem. 681, 2003, 196, and J. Chem. Soc. Dalton 1996, 4019; or as polynuclear metal complexes involving complex ligand bridging arrangements, as in V. W.-W. Yam et al, Organometallics 21, 2001, 721 and Organometallics 21, 2002, 4326, and Y.-D. Chen et al, Inorg. Chem. 43, 2004, 7493, where e.g. Pt(II) is one of the metals involved.

Phosphorescent chromophores incorporating the heavy metals described in the paragraphs above may also be incorporated as a core into dendrimers, as in e.g. J. M. Lupton et al, Adv. Funct. Mater. 11, 2001, 287, and other oligomeric structures which find utility in the systems according the present invention.

Phosphorescent polymers—in contrast to simple blending of the above chromophores and conventional polymer hosts—may facilitate solution deposition, reduce unstable phase behavior over longer term usage and protect against adverse photochemistry. These have the general structure of a conventional polymer backbone with a repetition of one or more attached pendant groups, at least one of which will have the form of the phosphorescent chromophores incorporating the heavy metals described in the paragraphs above, such as poly(Ir(ppy)₂(2-(4-vinylphenyl)pyridine))-co-vinyl carbazole)), as described in C. L. Lee et al, Opt. Mater. 21, 2002, 119, which uses a non-conjugated polyethylene backbone. Other examples using e.g. polycarbazole, polyfluorene, polystyrene, etc. backbones, as described in J. Jiang et al, J. Inorg. Organometallic Polymers and Materials, all incorporate the phosphorescent chromophores detailed above as pendant groups.

One example of a suitable photophosphorescent dye for use in the concentrator according to the present invention is tris[2-phenylpyridinato-C2,N] iridium(III), also known as Ir(Ppy)₃.

Preferably, for efficient phosphorescence, the material emits at the red end of the visible spectrum, preferably 550-750 nm, more preferably 600-700 nm, most preferably 650-700 nm. This allows maximum collection of the visible range without incurring a re-absorption penalty, whilst not suffering undue quantum loss (energy of the photons emitted ˜1/wavelength). An increasing non-radiative deactivation reduces the achievable quantum yield of phosphorescence.

The portion of the visible spectrum not covered by the phosphorescence is preferably covered by the formally-allowed absorption, and more preferably with one or more additional dyes, whose fluorescence overlaps strongly with the allowed absorption band of the phosphorescer, and whose concentrations facilitate efficient energy transfer to the phosphorescent dye.

Optionally, a mixture of photoluminescent dyes can be provided as the absorbing material of the concentrator according to the present invention. In this case, the mixture of dyes is preferably selected such that cumulatively there is a broad band of absorption in the visible region of the spectrum to enable a large proportion of the incident radiation to be absorbed across a range of wavelengths of actinic light, with a peak absorbance preferably in the shorter wavelength part of the spectrum and such that there is a narrow band emission spectrally separated from the region(s) of absorption, which should closely match the response of any associated radiation capture device such as a photovoltaic element.

The mixture of photoluminescent dyes may comprise a photophosphorescent material, which provides the spectrally separated emission and a second material, which may be a fluorescent dye, responsible for absorption of incident radiation. Ideally, the second material is such that in isolation it will emit at wavelengths with a high quantum yield of fluorescence closely matching the wavelength of excitation of the photophosphorescent material. In the presence of the photophosphorescent material, concentration conditions may be arranged to promote efficient resonant energy transfer, as described in T. Förster, “Fluorescenz Organische Verbindungen” Göttingen: Vandenhoech and Ruprech, 1951, to the singlet excited state of the photophosphorescent dye, without any intermediate fluorescent emission, and concomitant reabsorption attenuation. Preferably, the second material's emission and the wavelength of excitation of the photo-phosphorescent material is in the visible spectrum at a part of the spectrum where the second material absorbs relatively weakly whereby incident radiation can be absorbed by either or both the phosphorescent material and the second material, thus extending the effective spectral capture of the incident radiation. The phosphorescent material may be selected according to these criteria from any of the classes referred to above.

As a further option, the radiation-absorbing material may comprise a photophosphorescent dye embedded into the concentrating element and a thin, but separate layer of a broad-spectrum absorbing fluorescent dye having an emission matching that of the photophosphorescent dye, the layer of fluorescent dye being formed within the concentrator element or coated on the surface thereof, whereby the fluorescent dye absorbs incident radiation and emits fluorescence radiation that may be absorbed by the phosophorescent dye which emits emissive radiation suitable for use in the radiation capture device (e.g. of a bandwidth of response of an associated photovoltaic element).

Whilst in a planar concentrator element 75% of the emissive radiation is typically maintained within the element, so that 25% is routinely lost by passing out of the element again. Accordingly, as an option, means may be adopted to minimize the lost emissive radiation. In one embodiment described in the prior art, emissive losses may be minimized by incorporating a luminescent material within an aligned polymer arranged within a concentrator to minimize losses of incident radiation and emissive radiation. In an optional embodiment according to the present invention, there is provided a photophosphorescent dye disposed on an aligned polymeric material and incorporated into the concentrator element such as to minimize transmission losses of emissive radiation as described in WO-A-2006/088370, the general and specific disclosures of which are incorporated herein in relation to the incorporation of photophosphorescent dyes.

Optionally, a reflective element may be disposed on the side or sides of a concentrator element not subject to incident radiation to reflect back into the concentrator element any unabsorbed incident radiation, the reflective element optionally having disposed thereon a layer of photoluminescent material, e.g. particulate photoluminescent materials for generating diffuse light, which emits radiation at a wavelength closely matching the peak absorption of the embedded photoluminescent material.

The radiation-absorbing material, and in particular the photophosphorescent dye, may be embodied within the concentrator element by, for example, forming a coating of the absorbing material on an outer surface of the concentrator material, the coating having a refractive index similar to that of the concentrator element itself, by forming one or more layers of absorbing material within the concentrator element and/or by doping a phosphorescent dye and optionally any other components of the absorbing material into the concentrator element during its formation. Accordingly, the absorbing material and more particularly the phosphorescent dye may be incorporated into the concentrator element by means of one or more of doping, layering or coating.

The phosphorescent dye may be doped into the concentrator element by any suitable means depending upon the nature of the phosphorescent dye and the material of the element, but in any case would be expected to be incorporated during the formation of the element. For example, in the manufacture of a sol-gel type glass concentrator, the phosphorescent dye may be incorporated as a solution or dispersion in an aqueous solution of silicate salt which is then cured by acid precipitation and dehydration.

The absorbing material and phosphorescent dye may be incorporated by coating it on a surface of the concentrator element. For example, the dye may be coated directly onto the surface of the concentrator as a solution or dispersion in a suitable binder having a refractive index similar to that of the concentrator material itself, or it may be formed as a layer on one or both surfaces of a plastic film which may be then adhered to one or more surfaces of the concentrator, or alternatively the dye may be dispersed within a plastic film adhered to the surface of the concentrator. When formed as a photophosphorescent dye in a film coating, preferably an antioxidant is added to minimize oxidative degradation of the dye.

The absorbing material may be incorporated within the concentrator element itself by means, for example, of embedding the dye in the concentrator element by doping the concentrator material during formation with the dye. Alternatively or additionally, the dye may be incorporated in one or more layers, of similar refractive index, which one or more layers make up a single concentrator element, and wherein more than one layer contains the dye, they may be adjacent or separated layers. Optionally, a layer comprising a dye may be formed by doping a layer of material used to make the concentrator element with the dye or dyes and adhering with other layers of the concentrator element during or after formation. Optionally, one or more layers of the concentrator element, e.g. an internal layer containing a photophosphorescent dye, is a liquid having substantially similar refractive index to other solid and any other liquid layers of the element. The liquid may be a solution or dispersion of the absorbing element and/or phosphorescent dye. Optionally, the absorbing material and photophosphorescent dye may be embedded into the concentrator element by one or more of these means.

Where the absorbing material comprises a phosphorescent dye and one or more further components, such as a further phosphorescent dye, one or more fluorescent dyes or a material comprising quantum dots (e.g. as a radiation funnel feeding the phosphorescent dye with appropriately tuned radiation), the various components may be incorporated in combination or separately or a mixture thereof, e.g. by each separately or various combinations of coating, layering or embedding the various combinations into the concentrator element. For example, where the absorbing system comprises a photophosphorescent dye, a layer of quantum dots and one or more fluorescent dyes of suitably selected absorption and emission spectra according to the present invention, they may be arranged such that the phosphorescent dye is incorporated as a doped middle layer of the a three layer concentrator element, the quantum dots (which may be selected as appropriate in the manner described in U.S. Pat. No. 6,476,312, the disclosure of which is incorporated herein by reference) are formed in a separate layer of the concentrator element and the fluorescent dye(s) are incorporated by coating them on the surface of the concentrator element in a suitably selected binder material, or in any other arrangement.

The phosphorescent dye may be incorporated into the concentrator element, for use for example as a solar radiation concentrator, by for example embedding the dye into the media of the concentrating element, or host material. In such an embodiment, the phosphorescent material may be embedded in a host of thickness T cm and is square with side L cm. The decadic absorption coefficient of the material (measured in units of reciprocal distance) across the visible spectrum should be >0.1/T cm⁻¹, preferably >0.3/T cm⁻¹, more preferably >0.5/T cm⁻¹, most preferably 1/T cm⁻¹. The decadic absorption coefficient of the whole system at the wavelengths of phosphorescence should be less than 0.6/L cm⁻¹, preferably less than 0.3/L cm⁻¹, more preferably less than 0.1/L cm⁻¹. For a dye with a molar extinction coefficient of 5.10⁴ M⁻¹ cm⁻¹, if T=1 cm, for an absorption of 0.3 (50% of light absorbed) then the concentration of dye incorporated into the element would be 6 10⁻⁶M. In a window panel of L=50 cm length, for a maximum loss of 50% in transmitting the phosphorescence to the edge 25 cm away, say, the decadic absorption coefficient would be 0.012 cm⁻¹. This would require a molar extinction coefficient of not more than 0.012/6.10⁻⁶=2.10³ M⁻¹ cm⁻¹ Thus, in this example a reduction of 25× from the maximum absorption wavelength to the wavelengths of phosphorescent emission is required to avoid significant re-absorption losses.

Any suitable medium may be used as the material of the concentring element. One kind of concentrator material is a transparent plastic, such as an acrylic, polyurethane or polystyrene, doped with the absorbing material including a photophosphorescent dye. Another type of material is a “sol-gel” glass doped with the dye, the sol-gel glass being produced from an aqueous solution of silicate salt by acid precipitation and subsequent dehydration. Another type of material is a transparent low melting glass.

The concentrator element, and optionally therefore the waveguide, may be in sheet form, especially a planar sheet although curved panels and other configurations are considered to be within the scope of this invention, or, for example, in the form of a fiber optic cable.

The media in any case should be largely transparent at the luminescent wavelengths. The material acting as host to the phosphorescent dye (typically the medium of the concentrating element) and any additional dyes is preferably a polymer or other glassy material which is transparent in the visible spectrum, and has no lower-lying electronic excited states than the lowest excited states of the dyes. Preferably such host material is characterized by a Tg (a measure of rigidity) greater than 60° C., preferably greater than 100° C., more preferably greater than 150° C. and most preferably greater than 200° C. and in any case preferably has a Tg sufficient to guard against absorption of damaging levels of oxygen from the atmosphere into the medium. In this connection, it is preferable that the host material, or medium of the concentrating element according to the present invention, has an oxygen permeability of 10⁻² g/m²/day or less, more preferably 10⁻⁴ g/m²/day or less and still more preferably 10⁻⁶ g/m²/day or less.

Where more than one layer is utilized in the radiation collector, one of which being a collecting element hosting the absorbing material, it is preferred that the refractive index of the absorbing material or dye containing layer is equal to or greater than that of the outer surface layers, more preferably equal to that of any such surface layer.

For use in conjunction with photovoltaic elements, the waveguide and photovoltaic cells may be coupled via a taper of a transparent medium of higher refractive index, for example nanocrystalline diamond prepared by chemical vapor deposition, which may enable further useful concentration to be made further reducing the required size of photovoltaic element.

The medium of the concentration element or host material should be transparent throughout the visible region. The medium may, for example, contain the radiation-absorbing and re-emitting dye system as a single layer of doped media on its own, in a layer sandwiched between two outer surface layers of transparent material or as or as a dyed material with the same or different refractive index sandwiched between two lower refractive index, substantially transparent layers which are only poorly transmissive over longer path lengths.

For use as a solar concentrator for photovoltaics, the concentrator should be coupled appropriately to a photovoltaic element (e.g. at one or more edges, preferably all edges, of a planar sheet concentrator element). Any suitable photovoltaic element may be used provided the emission spectrum of the photophosphorescent dye and the photovoltaic cell response are matched appropriately. Types of suitable photovoltaic element include for example bulk or thin film elements, e.g. silicon cells, GaAs multijunction cells, copper-indium selenide cells, cadmium telluride cells, solar cells comprising dye-sensitizer mesoporous materials, organic/polymer solar cells or nanocrystalline solar cells such as solar dot or solar well photovoltaic cells (quantum well solar cell such as that described in WO-A-93/08606). Preferred PV elements according to this embodiment are those that are most efficient (e.g. silicone PV cells) and closely responsive to the preferred phosphorescent wavelengths, e.g. 650-700 nm.

In a preferred embodiment of the invention, the radiation concentrator is a planar or curved concentrator element that may suitably be used as a window pane and is optically coupled to one or more photovoltaic elements, e.g. at the edges of the concentrator element, such that the device may be incorporated into the built environment as windows in domestic or commercial buildings providing both a source of energy and a means of reducing heating in the building due to the solar radiation whilst maintaining a passage of light. Preferably, all edges of the concentrator element are coupled to PV cells.

Any suitable size of element may be utilized, but the size should be selected according to the loss as approximated by the equation earlier, which is dependent upon size of element. In a preferred embodiment, however, the concentrator element is a planar transparent sheet (or slightly curved sheet) of up to 1 m² and preferably at least 0.01 m², more preferably, the element is of an area in the range of from 0.09 to 0.56 m², still more preferably up to 0.36 m² and most preferably up to about 0.25 m².

In a further aspect of the invention, the absorbing material of the solar concentrator may comprise a mixture of at least two materials, an incident-absorptive component and a product-emissive component. The incident-absorptive component is characterized in that in the absence of the product-emissive component, it will emit a high quantum yield of fluorescence at wavelengths closely matching the wavelengths of absorption of the product-emissive component, whilst in the presence of the product-emissive component concentration conditions may be optimized such that efficient resonant energy transfer, as described in T. Förster, “Fluorescenz Organische Verbindungen” Göttingen: Vandenhoech and Ruprech, 1951, to the singlet excited state of the product-emissive component preferentially occurs. The peak of the quenched fluorescence emission of the incident-absorptive component should closely match the peak absorption of the product-emissive component to provide optimal overlap of the two profiles. The absorbing material is further characterized by the overall absorption of the incident-absorptive component and product-emissive component having a combined broader-band absorption capture of incident radiation, preferably in the visible spectrum, and the product-emissive component having a narrow band emission (product-emission) spectrum spectrally separated from the overall absorption spectrum. By this means, product emissions do not run the risk of being reabsorbed by either the incident-absorptive component or the product-emissive component, whilst the system is capable of broad-band visible absorption and narrow band emission at a wavelength to which the associated radiation capture device, e.g. PV element, is particularly responsive.

The incident-absorptive component may be chosen from any material which displays a significant visible absorption spectrum and a narrow band emission spectrum, the peak absorption and peak emission being spectrally separated. Under conditions of efficient resonant energy transfer, it is not required according to this aspect of the invention, that overlap of the absorption and emission spectra of the incident-absorptive component be avoided, merely that the material displays an intense, narrow-band emission spectrum spectrally separated from the peak absorbance wavelength. Accordingly, the incident-absorptive component may be provided by a fluorescent dye having one or more absorptions in the visible region and a narrow band emission and high quantum yield, or by an array of quantum dots having broad-band absorption and narrow band emission shifted relative to the peak of absorption. Suitable quantum dot configurations include, for example that described in U.S. Pat. No. 6,676,312, the disclosure of which is incorporated herein by reference in this context.

The product-emissive component may be chosen from any material which displays an absorption spectrum having a peak closely matching the narrow band emission spectrum of the of the incident-absorptive component and having a narrow band emission spectrum spectrally shifted with respect to the absorption spectra of both the product-emissive component and the incident-absorption component. The intermediate absorption may be a narrow band absorption. Suitable materials include photoluminescent materials, such as phosphorescent materials and fluorescent material. Suitable phosphorescent materials include those described above in relation to the other aspects of the present invention. Suitable fluorescent materials include those having narrow band absorption and emission spectra but characterized by large Stokes' shifts.

In a preferred embodiment of this aspect of the invention, the product-emission spectrum has minimal overlap with the absorption peaks of the components of the absorbing material, preferably amounting to losses (as defined above) of 5% or less of the total absorption intensity, more preferably 1% or less and still more preferably 0.2% or less of the total absorptive intensity of the absorption spectra of the incident-absorptive component and the product-emissive component.

The invention will now be described in detail, without limitation as to the scope of the invention, according to the following examples.

### EXAMPLES

### Example 1

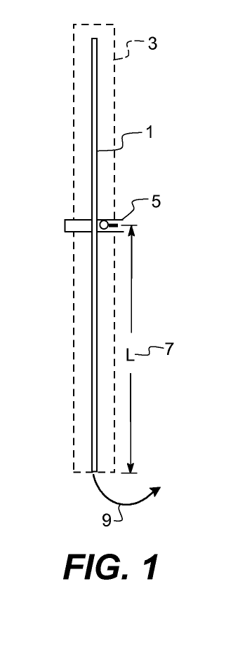

Two samples, one involving a conventional high quantum yield fluorescent dye, and one involving a high quantum yield phosphorescent dye belonging to the class claimed, were prepared to demonstrate the 1-dimensional efficiency of luminescence transmission. Glass tubes (45 cm length, 0.40 cm outer diameter, 0.24 cm. inner diameter, glass refractive index 1.47) were filled with individual dye solutions, which were prepared from a solvent or solvent mixture, whose refractive index was matched to that of the glass tube. The dye solutions under comparison were chosen to have nearly identical emission profiles with full-width half-maximum positions at approximately 500 nm and 560 nm. Solutions were excited by a 430 nm LED (3 mm diam.) at different positions along the tube, the different solutions under comparison were prepared to have the same absorbance at this excitation wavelength. The arrangement was as shown in FIG. 1, which shows a glass tube 1 filled with a dye solution surrounded by a screen 3 to shield the dye solution from external light, a moveable LED excitation source 5, to provide point illumination at varied distances L, 7, along the glass tube 1. The glass tube 1 is coupled with an optical fiber 9 to a spectrometer (not shown). The luminescence was monitored by coupling the column of dye solution to an optical fiber of 0.5 cm diameter, which was brought to the entrance slit of a mono-chromator and photomultiplier detection system. Attenuation of luminescent transmission was measured by monitoring a 10 nm bandwidth centered at approximately the maxima for both dyes, whist varying the position of the excitation source along the length of the tube.

Excitation was performed no nearer than 3 cm from the coupled fiber to avoid non-linear end-effects. Attenuation obeyed an exponential decay within experimental error over the range measured, in each case. Extrapolation to provide the 100% transmission point at 1=0 cm was made on this basis. TABLE 1 summarizes the data for two absorbance levels for each of the samples 1 and 2 (“comparison” and “invention” respectively). The choice and preparation of the samples was as follows:

### Sample 1

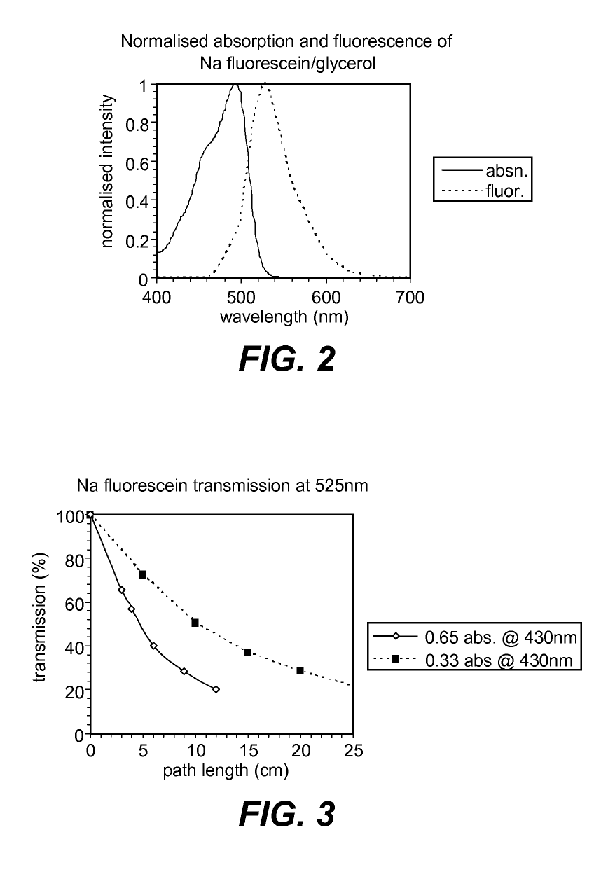

Two solutions of the sodium salt of fluorescein in glycerol (refractive index 1.47) were prepared having absorbances of 0.65 and 0.33 in a 1 cm cuvette at 430 nm. Care was taken with mixing to eliminate concentration gradients in the viscous solution. No special degassing precautions were taken; the luminescence arises from a singlet fluorescence, the solution is viscous, and oxygen quenching effects are not observed. The absorption and emission profiles are shown in FIG. 2. The attenuation of fluorescence transmission along the length of the tube for two absorbance levels at 430 nm are shown in FIG. 3.

### Sample 2

Two solutions of tris[2-phenylpyridinato-C2,N]iridium(III), also known as Ir(ppy)₃, were prepared in a toluene-ethyl acetate (1:0.4 v/v) solvent mixture, having absorbances of 0.66 and 0.31, respectively at 430 nm. The solvent mixture had a refractive index of approximately 1.47 and was rigorously saturated with nitrogen before and during the preparation. Solutions were maintained under a nitrogen atmosphere. A glass sample tube, previously sealed at one end with a silicone rubber sealant (Dow Corning 3140), was purged with nitrogen whilst filling. The second end was sealed under a nitrogen blanket with the same sealant, and all measurements were performed within 30 min. preparation.

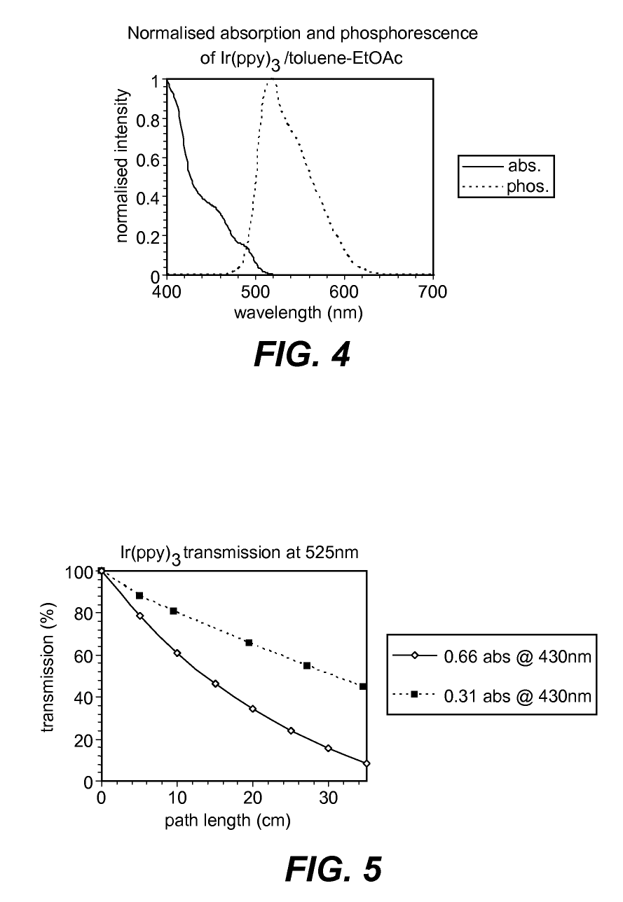

The absorption and emission profiles of Ir(ppy)₃ in toluene-ethyl acetate are shown in FIG. 4. The attenuation in transmission of phosphorescence along the length of the tube for two absorbance levels at 430 nm is shown in FIG. 5.

### Summary

By comparing the overlap of the absorption and emission profiles shown in FIGS. 2 and 4, the reabsorption advantage of the phosphorescent iridium case compared with the fluorescent sodium salt of fluorescein is evident. TABLE 1 shows that the advantage for a 1-dimensional system is about 3× in attenuation/unit length; comparing the same materials for a 2-dimensional surface the advantage would be expected to be almost an order of magnitude in effective collection area.

TABLE 1
Transmission attenuation for two luminescent dye solutions.

| | | Half-loss point (@ |
|---|---|---|
| Sample | Absorbance (@ 430 nm) | 525 nm) |
| 1. (Comparison) | 0.65 | 4.6 cm |
| | 0.33 | 9.7 cm |
| 2. (Invention) | 0.66 | 13.8 cm |
| | 0.31 | 30.7 cm |

Therefore the improved free path length of phosphorescent emission in a radiation collector element allows significant improvement in collector efficiency in a collector according to the present invention and so a larger collector surface may be utilized.

The invention has been described in detail with particular reference to certain preferred embodiments thereof, but it will be understood that variations and modifications can be effected within the spirit and scope of the invention.

1. A radiation concentrator comprising a radiation-transmissive element having a transmissive surface for receiving incident radiation, a radiation-absorbing material for absorbing incident radiation and emitting emissive radiation, a radiation output for transmitting concentrated emissive radiation and a wave-guide for guiding the emissive radiation to the radiation output, characterized in that the radiation-absorbing material comprises one or more photoluminescent dyes capable of phosphorescence, the dye or dyes exhibiting a high quantum yield of phosphorescent emission that is spectrally shifted from the material's absorption.

2. The radiation concentrator as claimed in claim 1, wherein the photoluminescent dye is a phosphorescent dye having a quantum yield of 0.1 or more.

3. The radiation concentrator as claimed in claim 1, wherein the radiation-absorbing material comprises an organometallic phosphorescent dye selected from second and third row transition metal complex phosphorescent dyes.

4. The radiation concentrator as claimed in claim 1, wherein the radiation-absorbing material comprises Ir(Ppy)₃.

5. The radiation concentrator as claimed in claim 1, in which the phosphorescent dye is doped into the radiation-transmissive element of the concentrator.

6. The radiation concentrator as claimed in claim 1, wherein the peak of the phosphorescent emission is spectrally shifted from the peak absorption by at least three times the sum of the half-width half-maximum values of the facing halves of the respective emission and absorption envelopes.

7. The radiation concentrator as claimed in claim 1, which is a planar concentrating element transmissive to solar radiation and which comprises the absorbing material and which surfaces define the waveguide.

8. The radiation concentrator as claimed in claim 7, wherein the radiation output is provided by one or more edges of said planar concentrating element.

9. An apparatus for converting incident radiation into electrical energy, said apparatus comprising a radiation concentrator as defined in claim 1, optically coupled to at least one photovoltaic element via the radiation output, wherein a phosphorescent dye provided in the radiation concentrator has an emission energy to which the photovoltaic element is responsive.

10. The apparatus as claimed in claim 9, wherein the incident radiation is solar radiation.

11. A method of capturing incident radiation comprising the steps of: providing a concentrating element with a surface transmissive to incident radiation, disposing on and/or within said element a radiation-absorbing material comprising a phosphorescent dye, the radiation-absorbing material being capable of absorbing at least a portion of said incident radiation and being capable of emitting emissive radiation spectrally shifted from its absorption spectrum; and providing in association with the element a radiation output for feeding concentrated radiation from the element, wherein the external surfaces of the element form a waveguide to direct emissive radiation to the radiation output.

12. The method of converting incident radiation into electrical energy comprising the steps defined in claim 11 for capturing incident radiation and the further step of providing a photovoltaic element to be optically coupled with the radiation output, whereby concentrated emissive radiation impinges upon said photovoltaic element, the emission spectrum of the phosphorescent dye and the response of the photovoltaic element being selected to be complementary.

13. A method of configuring a radiation concentrator said radiation concentrator comprising a radiation-transmissive element having a transmissive surface for receiving incident radiation, a radiation-absorbing material for absorbing incident radiation and emitting emissive radiation, a radiation output for transmitting concentrated emissive radiation and a wave-guide for guiding the emissive radiation to the radiation output, the radiation-absorbing material comprising one or more photoluminescent dyes capable of phosphorescence, the dye or dyes exhibiting a high quantum yield of phosphorescent emission that is spectrally shifted from the material's absorption, the method comprising the steps of:
selecting a radiation-transmissive element of a given size whereby the mean distance from the centre of the transmissive surface to the edge thereof is given by L;
selecting a dye having an extinction coefficient as a function of wavelength of ε(λ);
doping the transmissive element of the concentrator with the dye at a selected concentration c,
said size of element and identity and concentration of dye being selected such that the approximated loss factor is 0.5 or less, when given by the following formula
loss factor˜1−[∫10^{-ε(λ)c.L}.I(λ).(λ⁻²).dλ/∫I(λ).(λ⁻²).dλ]
wherein the integrations are over the wavelength range of the emission,
I(λ) is the relative intensity of the emission as a function of wavelength,
ε(λ) is the extinction coefficient (M⁻¹ cm⁻¹) of the dye's absorption as a function of wavelength,
c is the molar concentration of the dye in the absorbing medium and
L is a mean distance (cm) approximated as the distance from the centre of the medium area to its edge.

14. The method as claimed in claim 13, wherein the photoluminescent dye is a 2^{nd} or 3^{rd} row transition metal complex phosphorescent dye.

15. A radiation concentrator comprising a radiation-transmissive element having a transmissive surface for receiving incident radiation the surface having a size given by the mean distance from the centre of the transmissive surface to its edge of L, a radiation-absorbing material for absorbing incident radiation and emitting emissive radiation, a radiation output for transmitting concentrated emissive radiation and a wave-guide for guiding the emissive radiation to the radiation output, the radiation-absorbing material comprising one or more photoluminescent dyes capable of phosphorescence, the dye or dyes exhibiting a high quantum yield of phosphorescent emission that is spectrally shifted from the material's absorption and having an extinction coefficient as a function of wavelength of ε(λ) and incorporated into the concentrating element at concentration c, the radiation concentrator being configured such that
loss factor˜1−[∫10^{-ε(λ)c.L}.I(λ).(λ⁻²).dλ/∫I(λ).(λ⁻²).dλ]≦0.5
wherein the integrations are over the wavelength range of the emission,
I(λ) is the relative intensity of the emission as a function of wavelength,
ε(λ) is the extinction coefficient (M⁻¹ cm⁻¹) of the dye's absorption as a function of wavelength,
c is the molar concentration of the dye in the absorbing medium and
L is a mean distance (cm) approximated as the distance from the centre of the medium area to its edge.

16. An absorbing material for use in a radiation concentrator, the absorbing material comprising a mixture of at least two components, an incident-absorbing component and a product-emissive component, said incident-absorbing component being capable of absorbing radiation in the visible spectrum and in the absence of the product-emissive component capable of emitting radiation at a wavelength matched to the absorption spectrum of the product-emissive component, the product-emissive component comprising at least one phosphorescent dye having a high quantum yield of phosphorescence at a desired wavelength that is spectrally shifted from the absorbance of the absorbing material.
